(19) United States
(12) Patent Application Publication
(10) Pub. No.: US 2025/0020878 A1
(43) Pub. Date: Jan. 16, 2025

(54) OPTO-ELECTRONIC ASSEMBLY

(71) Applicant: HiLight Semiconductor Limited, Southampton (GB)

(72) Inventor: Carl CARLEY, Southampton (GB)

(21) Appl. No.: 18/771,778

(22) Filed: Jul. 12, 2024

(30) Foreign Application Priority Data
Jul. 14, 2023 (GB) 2310827.7

(51) Int. Cl. G02B 6/42

(52) U.S. Cl. CPC G02B 6/4228; G02B 6/4204; G02B 6/4281

(57) ABSTRACT

An assembly of electronic components providing means for reception of data using an optical fibre wherein said assembly comprises: a photodiode; an amplifier coupled to said photodiode a printed circuit board, said photodiode and amplifier physically mounted on a first side of said printed circuit board; and a stiffener attached to said printed circuit board, wherein said stiffener is attached in a region approximately concentric with said region of said printed circuit board whereon said photodiode and amplifier are mounted, and conducting bond wires configured to directly couple said amplifier and said photodiode to conducting traces on a second opposite side of said printed circuit board with respect to said amplifier and said photodiode; and a fibre alignment ferrule and lens cap assembly, wherein said fibre alignment ferrule and lens cap assembly comprises: a ferrule which is configured to configured to provide a receptacle with defined physical alignment for an optical fibre; a lens which is configured to focus light from said optical fibre on to said photodiode; a cover region configured to provide an hermetic seal for said amplifier and said photodiode, wherein said fibre alignment ferrule and lens cap assembly is configured to be physically attached to said printed circuit board so as to provide an hermetic seal for said photodiode and amplifier and to further align said lens within said fibre alignment ferrule and lens cap assembly so as to focus light from said optical fibre onto said photodiode.

### CROSS-REFERENCE TO RELATED APPLICATION

This application claims priority to, and the benefit of, United Kingdom Application No. 2310827.7, filed on Jul. 14, 2023, the entire contents of which are incorporated herein by reference in its entirety for all purposes.

### FIELD OF THE INVENTION

The present application relates to opto-electronic assemblies and receive optical sub-assembly construction with a fibre alignment ferrule and lens cap attachment for chip-on-flex assembly.

### BACKGROUND OF THE INVENTION

High speed optical communication links comprise many optical, electronic and opto-electronic components and assemblies wherein electrical signals are converted into optical signals for transmission over a fibre; and where optical signals conveyed by means of a fibre are converted to an electrical signal and subject to amplification and further processing. Common requirements for the components and assemblies used in such links are that the cost be minimised, while at the same time the performance is to be maximised.

This invention is concerned with that part of an optical communications system wherein an optical signal is received and converted into an electrical signal and subject to amplification and possibly also subject to other signal processing functions before being conveyed to other components of the complete signal chain. The receive functions in one sub-assembly may in some cases be combined with transmit functions contained in another sub-assembly into a larger assembly. The features of the invention to be described are applicable for an assembly intended for the receive path of an optical communications system or for use in a combined assembly for both receive and transmit paths, and where the description refers to a receive function, it should be taken that the features may also be used in a combined assembly.

Such a receive path component is commonly called a Receive Optical Sub-Assembly or ROSA, and may comprise a photodiode and an associated amplifier, typically a trans-impedance amplifier, possibly with an associated internal limiting amplifier. The associated amplifier is typically mounted close to the photodiode in order to maximise the bandwidth of the complete system. Conventionally the photodiode and the amplifier are mounted in a metal can wherein the external electrical connections are provided by means of wire leads that feed through insulating regions in the base of the can and wherein said leads further provide posts within the can to which wires may be bonded. These wires may also be bonded to pads on the amplifier integrated circuit and also on to pads on the photodiode. By these means power, monitoring, control and signal paths are established. The wire leads from the can are then connected to a flexible printed circuit board (PCB) and this flexible board is further connected to the main electrical functions of a receiver module.

Such metal cans represent a significant proportion of the total cost of the ROSA. Further, there is an inherent impediment to achieving the highest possible operating bandwidth since it is necessary for the high data rate output signals from the amplifier to pass in turn through bond wires, header posts, lead wires and then via conductive traces in a flexible PCB before being communicated to the next electronic functions in the signal chain.

It is possible for manufacturing and assembly costs to be reduced and at the same time for high frequency performance to be improved by means of mounting the electronic components in the ROSA directly on the flexible PCB and thereby reducing the overall length of the signal path for the received signals.

However, in a practical implementation of such an assembly it is necessary to provide a cover for the said electronic components and the photodiode where said cover also provides an optical aperture containing the lens used to focus light from the fibre onto the photodiode. In addition, there is a requirement to provide mechanical support for the electronic and optoelectronic components on the flexible PCB. Without such support, there is a possibility that there will be failures in connections or in the adhesion of the said components to the PCB. There is also a need to provide means for aligning the said lens with the sensitive region of the photodiode, and securing this in position during the operational deployment. Any means of attaching said cover and lens assembly to the PCB to fulfil these requirements should preferably meet the further requirements of being low cost and reliable and be achieved by means of assembly methods compatible with conventional PCB manufacturing processes.

### SUMMARY OF THE INVENTION

It is an object of the invention to provide means of construction and configuration for the receiving function of a high speed optical communication system wherein manufacturing cost is reduced compared with prior art. It is a further object of the invention to provide a construction and configuration for the receiving function of a high speed optical communication system wherein improved performance can be achieved compared with prior art.

A benefit of the invention is that the requirement to use fully enclosed cover for the mounting of the photodiode and the associated amplifier is avoided by mounting the principal electronic components directly on the flexible PCB.

A further benefit of the invention is that the flexible PCB is mechanically supported under the region wherein the photodiode and amplifier and associated components are mounted by a low cost stiffener that provides local mechanical stiffness to reduce the risks of deformation of the PCB that could lead to misalignment or breakage and thereby reduces the mechanical requirements for any cover and lens assembly.

A yet further benefit of the invention is that the means for covering the photodiode, amplifier and other electronic components also provides for the mounting of the lens and further provides a receptacle for the fibre eliminating the need for a separate fibre alignment ferrule assembly.

According to a first aspect of the invention there is provided an assembly of electronic components providing means for reception of data using an optical fibre wherein said assembly comprises: a photodiode; an amplifier coupled to said photodiode; a printed circuit board, said photodiode and amplifier physically mounted on a first side of said printed circuit board; and a stiffener attached to said printed circuit board, wherein said stiffener is attached in a region approximately concentric with said region of said printed circuit board whereon said photodiode and amplifier are mounted, and conducting bond wires configured to directly couple said amplifier and said photodiode to conducting traces on a second opposite side of said printed circuit board with respect to said amplifier and said photodiode; and a fibre alignment ferrule and lens cap assembly, wherein said fibre alignment ferrule and lens cap assembly comprises: a ferrule which is configured to configured to provide a receptacle with defined physical alignment for an optical fibre; a lens which is configured to focus light from said optical fibre on to said photodiode; a cover region configured to provide an hermetic seal for said amplifier and said photodiode, wherein said fibre alignment ferrule and lens cap assembly is configured to be physically attached to said printed circuit board so as to provide an hermetic seal for said photodiode and amplifier and to further align said lens within said fibre alignment ferrule and lens cap assembly so as to focus light from said optical fibre onto said photodiode.

Said stiffener may be attached to a second side of said printed circuit board opposite to said photodiode and amplifier.

Said assembly may further comprise ancillary electronic components mounted on said printed circuit board and covered by said fibre alignment ferrule and lens cap assembly.

An area of said first side of said printed circuit board may have a first region that substantially matches an outline of said contact region of a base of said fibre alignment ferrule and lens cap assembly and said first region of said printed circuit board has applied thereto a layer of adhesive, wherein said adhesive permits adjustment of attached components until a curing process is performed.

Said region whereon there is applied said adhesive may be arranged in a concentric manner around a location of said photodiode.

Said fibre alignment ferrule and lens cap assembly may be attached to said first side of said first region of said printed circuit board by said adhesive.

Holes may be formed through said first region of said printed circuit board of sufficient diameter to permit said adhesive to flow though said holes when said adhesive is applied to said first region.

Said first region of said printed circuit board may have applied thereto a layer of said adhesive, wherein said adhesive is sufficiently fluid to flow through said holes in said first region, and wherein said adhesive permits adjustment of attached components until a curing process is performed.

Said fibre alignment ferrule and lens cap assembly and said stiffener may be attached to said printed circuit board by said adhesive applied to said first region and wherein said adhesive has been made to flow through said holes in said first region.

A final position of said fibre alignment ferrule and lens cap assembly may be adjusted to provide satisfactory coupling of optical signals to said photodiode; and after said adjustment is completed said adhesive is subject to a curing process to fix said position of said fibre alignment ferrule and lens cap assembly.

A vent hole may be provided to allow gas pressure differences between an inside of said fibre alignment ferrule and lens cap assembly and an external atmosphere to be released.

According to a second aspect of the invention there is provided a method of assembly of electronic components to provide means for reception of data using an optical fibre, said method comprising: providing a printed circuit board, wherein said printed circuit board is configured to have conducting traces in defined regions; physically mounting on a first side of said printed circuit board a photodiode and an amplifier; providing a stiffener, wherein said stiffener is attached in a region approximately concentric with said region of said printed circuit board upon which said photodiode and amplifier are mounted; providing on said printed circuit board holes through said board configured to provide means of electrical connection between opposite sides of said printed circuit board; providing a fibre alignment ferrule and lens cap assembly, wherein said fibre alignment ferrule and lens cap assembly comprises: a ferrule which is configured to configured to provide a receptacle with defined physical alignment for an optical fibre; a lens which is configured to focus light from said optical fibre on to said photodiode; a cover region configured to provide an hermetic seal for said amplifier and said photodiode;

physically attaching said fibre alignment ferrule and lens cap assembly to said printed circuit board so as to provide an hermetic seal for said photodiode and amplifier; aligning a position of said fibre alignment ferrule and lens cap assembly such that said lens within said fibre alignment ferrule and lens cap assembly is able to focus light from said optical fibre onto said photodiode.

Said stiffener may be attached to a second side of said printed circuit board opposite to said photodiode and amplifier, and said fibre alignment ferrule and lens cap assembly may be configured to cover said photodiode and said amplifier on said printed circuit board.

Said printed circuit board may be a flexible printed circuit board.

Fibre alignment ferrule and lens cap assembly may be attached to said printed circuit board using an adhesive, wherein said adhesive is configured to permit adjustment of said position of said fibre alignment ferrule and lens cap assembly before curing of said adhesive.

At least one said hole may be provided within a region of said printed circuit board covered by said fibre alignment ferrule and lens cap assembly.

Connections between said conductive traces on said printed circuit board and said photodiode may be made via said at least one hole provided within said region of said printed circuit board.

### SUMMARY OF THE FIGURES

The invention will now be described solely by way of example and with reference to the accompanying drawings, in which:

FIG. 1 shows a fibre optical communications system according to prior art.

FIG. 2 shows a view of a ROSA mounted on a flexible PCB for use in a fibre optical communications receiver according to prior art.

FIG. 3 shows a further view of a ROSA and the associated fibre connection for use in a fibre optical communications receiver module according to prior art.

FIG. 4 shows an assembly of components for part of a fibre optical receiver configured according to an embodiment of the present invention.

FIG. 5 shows a further assembly of components for part of a fibre optical receiver configured according to an embodiment of the present invention.

FIG. 6 provides another view of the exemplar arrangement shown in FIG. 5 according to an embodiment of the invention.

FIG. 7 shows a procedure for a method of assembly of components according to some aspects of the invention.

Note that the description is not to be taken in a limiting sense but is made merely for the purposes of describing the general principles of the embodiments of the invention.

### EMBODIMENTS OF THE APPLICATION

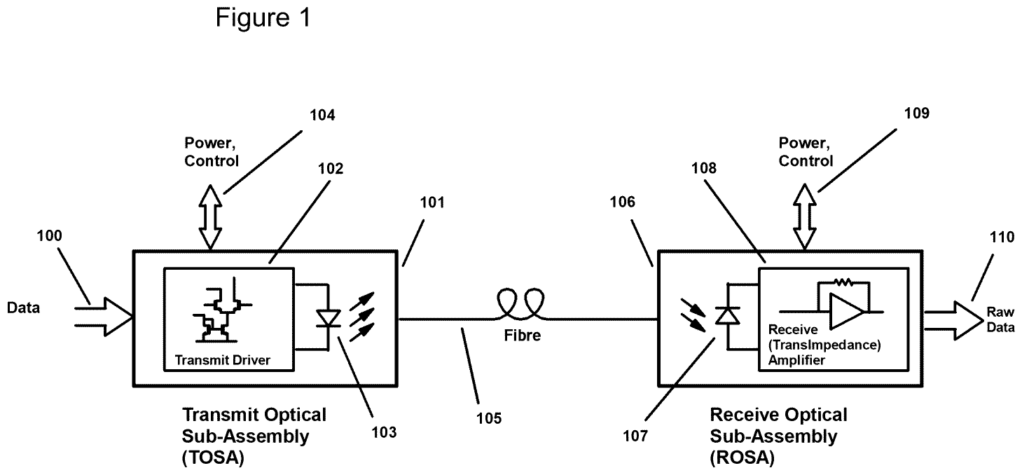

FIG. 1 shows the basic system level configuration of a generic optical communications physical link according to prior art, wherein electrical data signals 100 containing information are converted to optical signals in a Transmit Optical Sub-Assembly (TOSA) 101, where said TOSA may be comprised of driver electronics 102 and typically a laser diode 103 or other electro-optical conversion device. The driver electronics provide the laser diode (or alternative device) with appropriate current waveforms necessary to create the desired optical signal representing the electrical data signals. There may be constraints imposed in order to respect further requirements imposed by agreed performance standards and specifications. The driver electronics may be a combination of components or have nearly all the necessary functions integrated in a single integrated circuit (IC). The TOSA will also have additional connections 104 to provide power supplies and may also have control and monitoring inputs and outputs.

After travelling along the fibre 105, the optical signal is converted back to an electrical signal representing the data in a Receive Optical Sub-Assembly (ROSA) 106. Said ROSA may be comprised of a photodiode 107 to perform the basic conversion of the optical signal into an electrical signal, where said photodiode is coupled to an amplifier 108, typically, though not exclusively, a transimpedance amplifier (TIA), in order to deliver a usefully large raw data signal 110 that may be conveyed to electronic components and systems for further processing. The amplifier 108 is typically mounted very close to the photodiode 107 in order to minimise stray capacitance and inductance effects that could have detrimental impacts on the speed of operation. The ROSA will also have additional connections 109 to provide power supplies and may also have control and monitoring inputs and outputs. The output 110 of said amplifier is typically passed to a limiting amplifier wherein the magnitude of the signal is raised and compensation made for variations in the strength of the optical signal in order to make it suitable for further processing, often by digital circuits.

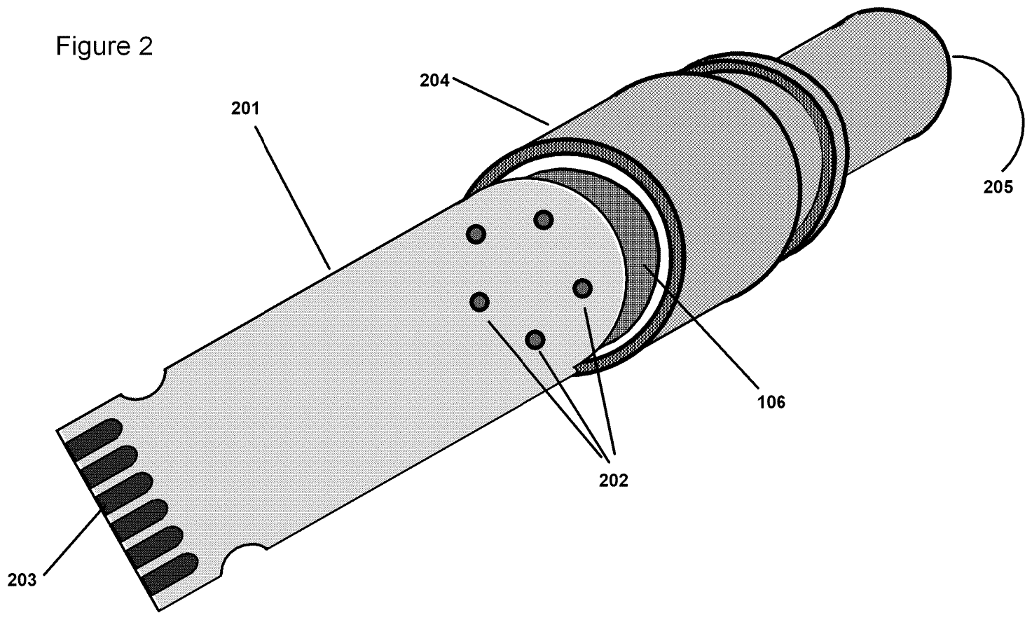

FIG. 2 shows a diagrammatic representation of a ROSA 106 mounted on a flexible printed circuit board (PCB) 201 according to prior art, where in this view represented in the figure the aperture for the fibre 205 to provide the optical input for the ROSA is facing away. In order to allow for the alignment of the ROSA with the incoming fibre 105 and thus couple the optical signal effectively to the sensitive face of the photodiode 107 it is commonplace to mount the ROSA on a flexible printed circuit board (PCB) with wire leads from the ROSA soldered into holes 202 in the PCB 201. Said PCB 201 typically carries no components apart from the ROSA and is usually solely employed for coupling the signal and power connections 109, 110 from the ROSA to the host electronic system, with an array of edge connections 203 typically provided at one end of the said PCB 201. The ROSA itself typically has an overlay tube structure (sometime described as a ferrule) 204 attached thereto that forms part of the means for connecting and aligning the fibre 105 with the photodiode 107 contained in the ROSA.

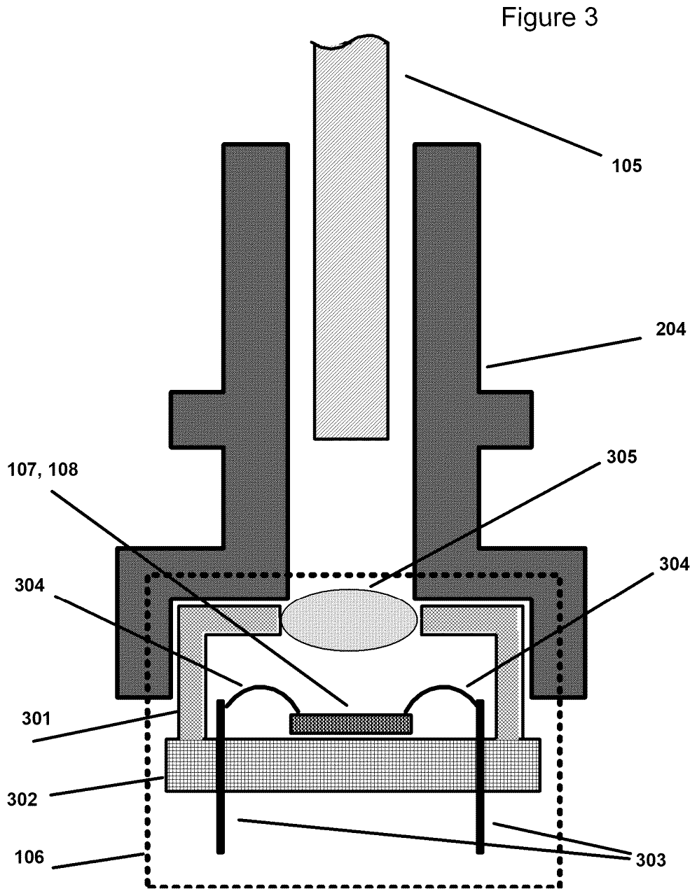

FIG. 3 shows a cross-sectional view of a typical ROSA 106 construction together with the associated components used to connect and align the fibre 105 with the photodiode 107 contained in the ROSA, according to prior art. The ROSA itself is typically housed within a metal can 301 similar to those used to house discrete transistors, often referred to as “TO” cans. Said cans are typically of the order of 5 mm in diameter and 3 mm in height not including the electrical leads. The base 302 of the can 301 may be of an insulating material or have insulating regions allowing conducting leads 303 to pass through to the internal cavity of the can. The photodiode 107 and (transimpedance) amplifier 108 are mounted within the can (in this figure these components are one behind the other and thus not represented individually) and electrical connections made to the leads 303 by means of bond wires 304. Said bond wires are typically gold wires of the order of one or two millimetres in length. At the top of the can there is typically an opening into which is mounted a lens 305 employed to focus the light from the fibre onto the photodiode. Note that in FIG. 3 there are spaces shown between the fibre alignment ferrule 204 and the ROSA can 301, as well as between the fibre alignment ferrule and the incoming fibre 105, but these spaces are merely to show the individual components more clearly. In a practical implementation it will be obvious to one of ordinary skill in the arts that the fibre alignment ferrule 204 will be made to be a close fit over the ROSA can 301 and similarly a close fit for the fibre 105 in order to ensure correct alignment of the fibre with the ROSA's optical aperture and lens 305.

It will be apparent to one of ordinary skill in the arts that there is a significant cost associated with the construction of the ROSA both in parts for the can, lens mounting, and fibre alignment ferrule and in terms of labour involved in assembling the complete ROSA on to the flexible PCB. A further issue is that the signal path from the (transimpedance) amplifier 108 to the edge connector 203 of the flexible PCB comprises passes through several media comprising a bond wire 304, ROSA lead 303 and thence through the conducting traces of the PCB. At each change in the signal path medium there will inevitably be some change in the characteristic impedance experienced by the signal, and with various different reflection and attenuation characteristics evident. At the desired operating data rates for such optical communications, typically up to 10s of Gbits/s, such effects can have a significantly detrimental impact on signal transmission.

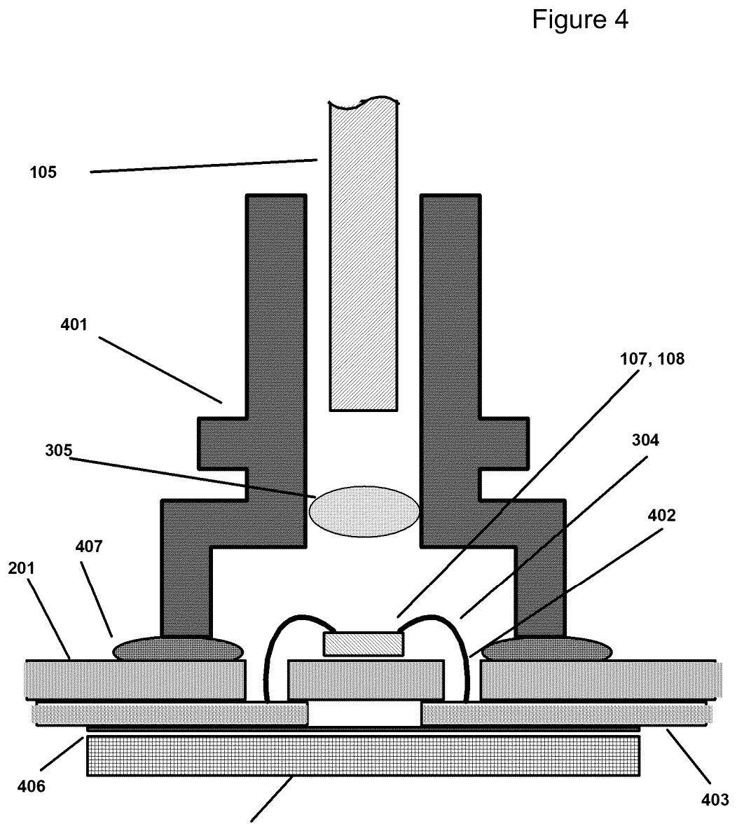

FIG. 4 shows an exemplar arrangement for an alternative form of ROSA that seeks to improve on some of the shortcomings of the previously described prior art according to some embodiments of the invention. The photodiode 107 and amplifier 108 and any associated components are mounted directly on the flexible PCB 201. The ROSA can base 302 and the metal leads 303 (as shown in FIGS. 2 and 3) are no longer required for this arrangement, and the photodiode 107 and the (transimpedance) amplifier 108 have been mounted directly on the flexible PCB 201.

In the prior art as exemplified in FIG. 3, the ROSA 106 was attached to the flexible PCB 201 by means of the ROSA leads 303 which also provided the electrical power and signal paths. In the new arrangement shown in FIG. 4 these leads are not present and the electrical connections from the amplifier 108 and other components in the ROSA to the conducting traces 403 of the flexible PCB are made more directly. Holes 402 are cut in the insulating layer of the PCB 201, typically a polyimide material, so that suitably located areas of the conductive traces (typically copper) on the back side of the PCB are now accessible. With a hole of sufficient size, it is now possible to connect a bond wire 304 directly from the amplifier 108 or other component within the ROSA to the corresponding conducting trace 403. In this way the characteristic impedance discontinuities and parasitic impedances present in the signal paths will be further reduced and so allow improved high frequency performance to be achieved. The holes 402 in the PCB 201 are obviously required to be of sufficient diameter to permit the bond wires leading from the amplifier and other components to be placed and secured on the conductive traces 403 on the back of the PCB. In practice, the diameter of said holes need not be excessively large, and in practice it is possible to place sufficient holes within the diameter of a conventional ROSA and still have ample space on the PCB surface within any ROSA assembly to place the photodiode 107 correctly and to place the amplifier 108 as well as any necessary ancillary components. In order for the conductive traces 403 to remain securely affixed to the back of the PCB during and after the wire bonding process, it is convenient to make the ends of the traces of a larger diameter than the holes 402 cut for the bond wires 304 such that this region of the conductive trace has support around the entire periphery of the hole 402. The layout of the traces from the holes to the edge of the flexible PCB may then be laid out in such a manner as to ensure that the characteristic impedance is maintained as close to the ideal desired value as possible.

FIG. 4 also show a combined fibre alignment ferrule and lens cap component 401 is provided which combines the functions of the cover can 301 and the fibre alignment ferrule 204 and completely replaces those components, furnishing a significant reduction in material cost. Said fibre alignment ferrule and lens cap 401 is configured so that it holds the lens 305 in an opening between the location provided for the end of the fibre 105 and the photodiode 107 mounted on the PCB 201. Said fibre alignment ferrule and lens cap 401 is mounted directly on to the flexible PCB so as to provide a cover for the photodiode 107 and the amplifier 108 using an adhesive layer 407.

In some embodiments it may be convenient to fix a stiffener element 405 to a side of the PCB 201 opposite to the side whereon the photodiode 107 and amplifier 108 are to be mounted, said stiffener being of sufficient mechanical rigidity to ensure that there are no significant distortions possible in the PCB that could lead to mechanically induced failures in the ROSA either during any assembly and test processes or during its operational life. Said stiffener may be made from stainless steel, fibreglass or any other convenient material, and may be attached to the PCB using an adhesive layer 406 or other suitable means. In other embodiments the attachment of the fibre alignment ferrule and lens cap 401 may provide sufficient stiffness to the flexible PCB in the region whereon are mounted the photodiode and amplifier and any associated components such that the risks of mechanically related failures are negligible.

It will be understood by one of ordinary skill in the art that some alignment of the position of the fibre alignment ferrule and lens cap 401 is likely to be necessary in order to ensure that the optical signal from the fibre 105 is coupled to the photodiode 107 in an optimal manner. This alignment process may be conveniently undertaken when the fibre alignment ferrule and lens cap 401 has been placed on the PCB with the required adhesive placed between the fibre alignment ferrule and lens cap and the PCB, but has not yet been cured.

The ROSA assembly may be mounted in a test jig with temporary connections made from the edge connector 203 of the PCB 201 to suitable analytical equipment and then an optical signal applied via a fibre inserted in the receptacle in the fibre alignment and lens cap 401. Adjustment of the position of the fibre alignment ferrule and lens cap 401 may then be undertaken so as to achieve an optimum electrical output from the ROSA into the analytical equipment, whereupon the adhesive 407 placed to fix the fibre alignment ferrule and lens cap to the PCB 201 may be cured or partially cured, for example, using ultraviolet light.

It may be convenient to undertake this alignment process in an inert gas atmosphere such that the photodiode, amplifier and any other electronic components are sealed in said atmosphere when the adhesive is cured to form a seal. Alternatively, it may be convenient to undertake the alignment process in a normal ambient atmosphere and further to cure or partially cure the adhesive holding the fibre alignment ferrule and lens cap to the PCB. Following this alignment process, the cavity within the fibre alignment ferrule and lens cap may be evacuated and may be filled with an inert gas, whereupon a provided vent hole is then sealed using a suitable adhesive or sealant material. Further curing of the adhesive regions may then be undertaken if required.

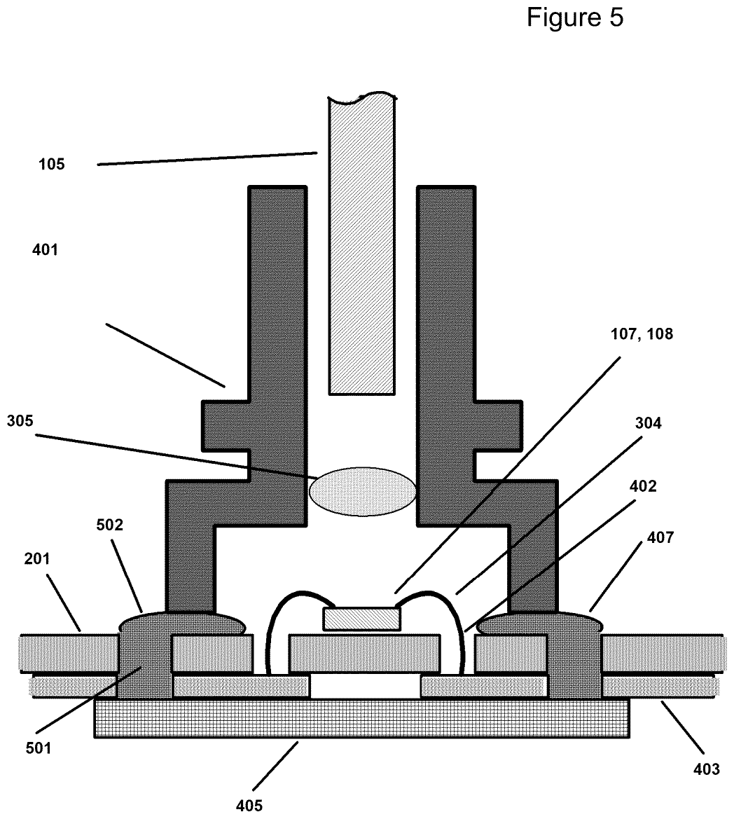

FIG. 5 shows another exemplar arrangement for an alternative form of ROSA according to some embodiments of the invention wherein further time and cost savings in the assembly process may be achieved. Additional holes 501 are formed in the PCB 201 in a region that follows the outline of the base of the fibre alignment ferrule and lens cap 401 where it is intended to attach to the PCB 201, said holes being configured to pass through any regions of conductive track 403 that may lie on an opposite side of the PCB from the photodiode 107 and amplifier 108. When an adhesive 502 is applied in the region of the intended joint, where prior to any curing process said adhesive has properties allowing it to flow through the said holes 501, then said adhesive and may be used to affix a stiffener 405 to said opposite side of the PCB 201 with a bond between the fibre alignment ferrule and lens cap 401 and the PCB 201 and the stiffener 405. In this way a step in the assembly process is eliminated together with the associated costs.

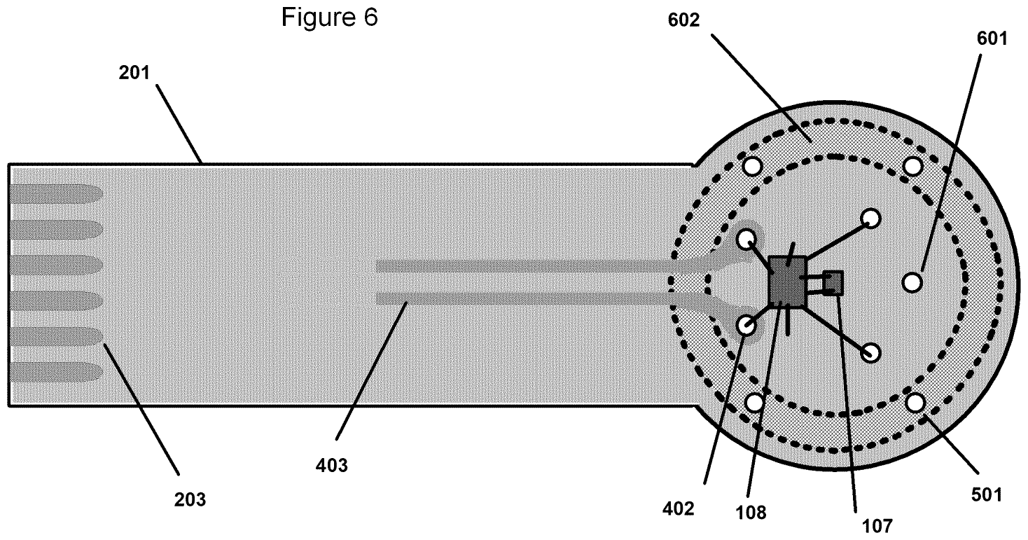

FIG. 6 provides another view of the exemplar arrangement shown in FIG. 5 above for an alternative form of ROSA according to some embodiments of the invention, showing the arrangements on the side of the PCB 201 whereon the photodiode 107 and amplifier 108 are mounted without the fibre alignment ferrule and lens cap 401. The fibre alignment ferrule and lens cap 401 is to be attached so that the base of said fibre alignment ferrule and lens cap aligns with a region 602 surrounding the location of the said photodiode and said amplifier. Within the boundaries of said region 602 there are provided holes 501 through which adhesive is able to flow to provide a bond between said fibre alignment ferrule and lens cap 401 and said PCB 201 and said stiffener 405.

In this exemplar arrangement there is also provided a hole 601 in the said PCB 201 located within a region that will become enclosed by the said fibre alignment ferrule and lens cap 401 whose purpose is to provide a vent for gases that may be trapped within said fibre alignment ferrule and lens cap after is has been fixed by means of said adhesive. In the case that assembly has been undertaken in a normal air environment, it will be desirable to evacuated and/or purge the cavity within the fibre alignment ferrule and lens cap. There may also be the requirement to replace any gases within the cavity within said fibre alignment ferrule and lens cap with inert gases.

When any evacuation or purging and gas replacement process has been completed, said vent hole 601 may be sealed with adhesive and said adhesive cured to form a permanent seal.

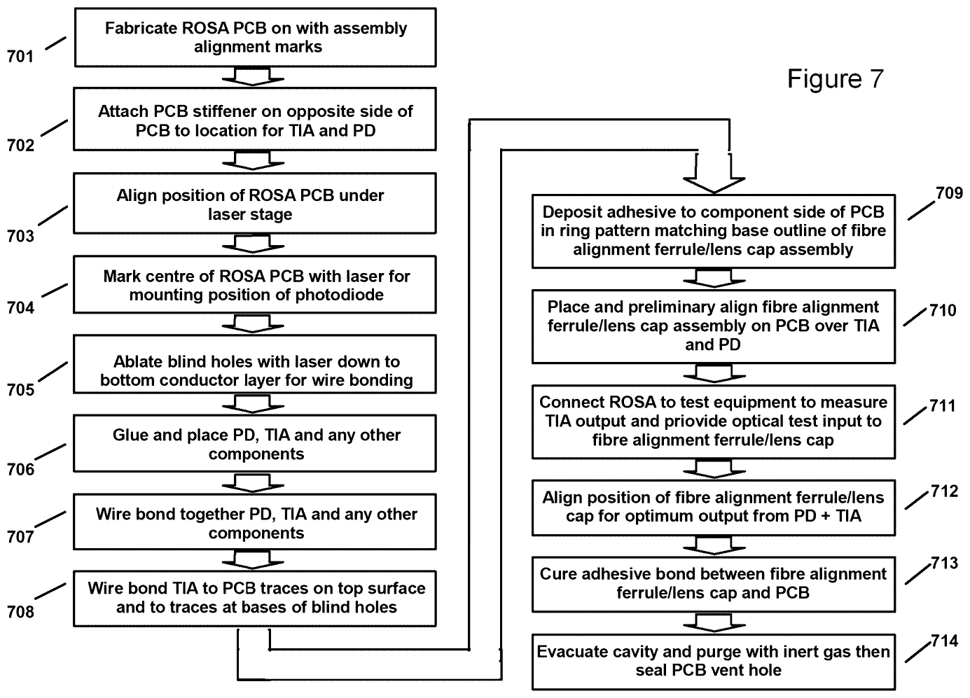

FIG. 7 shows an exemplar method for the assembly of components according to some embodiments of the invention. It will be understood that many variations of this method and other different methods are possible to achieve the objectives of the invention.

Thus there is a first operation of fabricating a ROSA PCB with assembly alignment marks as shown in FIG. 7 by step 701.

Then a stiffener is attached using adhesive on an opposite side of said ROSA PCB to an amplifier and photodiode under the region wherein are located the photodiode, and amplifier and other components as shown in FIG. 7 by step 702.

Then the position of each ROSA PCB 201 is aligned in turn under a laser stage as shown in FIG. 7 by step 703.

Then the centre of the ROSA PCB is marked with a laser to indicate the mounting position of photodiode as shown in FIG. 7 by step 704.

Then the holes for through-hole wire bonding are formed by ablating the PCB insulating material with a laser as shown in FIG. 7 by step 705.

Then the photodiode 107, (transimpedance) amplifier 108 and any other components are placed and affixed to the PCB with adhesive or by other suitable means at their designated positions as shown in FIG. 7 by step 706.

Next, the photodiode, (transimpedance) amplifier and any other components are electrically connected together and to the PCB traces and ground plane by means of wire bonding as shown in FIG. 7 by step 708.

Next, a region of adhesive is applied to the top side of the PCB in a ring pattern or other suitable pattern matching the base of the fibre alignment ferrule and lens cap assembly as shown in FIG. 7 by step 709.

Next the fibre alignment ferrule and lens cap assembly is placed on the PCB to cover the photodiode and amplifier and any other components in a position that is close to the expected final position, preferably in an inert atmosphere, as shown in FIG. 7 by step 710.

Next, while maintaining the inert atmosphere, the output of the amplifier is connected to suitable test equipment, said equipment being capable of determining when the signal from the photodiode is optimal, and an optical signal is provided through the fibre alignment ferrule and lens cap assembly as shown in FIG. 7 by step 711.

Next, while maintaining the inert atmosphere, the fibre alignment ferrule and lens cap assembly are aligned so as to provide the optimal output from the photodiode as indicated by the signals sensed by test equipment connected to the amplifier, as shown in FIG. 7 by step 712.

Next, the adhesive layer between the fibre alignment ferrule and lens cap assembly and the PCB is cured using ultraviolet light or by other suitable means to permanently fix the fibre alignment ferrule and lens cap assembly to the PCB as shown in FIG. 7 by step 713.

Finally, evacuate and purge the cavity inside the fibre alignment ferrule and lens cap assembly with inert gas and seal the vent hole with adhesive and cure the said adhesive as shown in FIG. 7 by step 713.

Whilst this invention has been described with reference to particular examples and possible embodiments thereof, these should not be interpreted as restricting the scope of the invention in any way. It is to be made clear that many other possible embodiments, modifications and improvements may be incorporated into or with the invention without departing from the scope and spirit of the invention as set out in the claims.

What is claimed is:

1. An assembly of electronic components providing means for reception of data using an optical fibre wherein said assembly comprises:
a photodiode;
an amplifier coupled to said photodiode
a flexible printed circuit board, said photodiode and amplifier physically mounted directly on a first side of said flexible printed circuit board; and
a stiffener attached to said flexible printed circuit board, wherein said stiffener is attached to a second side of said flexible printed circuit board opposite to said photodiode and amplifier, and wherein said stiffener is attached in a region approximately concentric with said region of said flexible printed circuit board whereon said photodiode and said amplifier are mounted, and
conducting bond wires configured to directly couple said amplifier and said photodiode to conducting traces on a second opposite side of said flexible printed circuit board with respect to said amplifier and said photodiode; and
a fibre alignment cover and lens cap assembly, wherein said fibre alignment cover and lens cap assembly comprises:
a combined fibre alignment ferrule and lens cap component, configured to provide a receptacle with defined physical alignment for an optical fibre, and to further configured to provide a cover region configured to provide an hermetic seal for said amplifier and said photodiode, and which is further configured to hold a lens in an opening between the end of said fibre and said photodiode:
a lens which is configured to focus light from said optical fibre on to said photodiode;
wherein said combined fibre alignment ferrule and lens cap component is configured to be physically attached to said flexible printed circuit board so as to provide an hermetic seal for said photodiode and amplifier and to further align said lens within said fibre alignment ferrule and lens cap assembly so as to focus light from said optical fibre onto said photodiode.

2. The assembly as claimed in claim 1 wherein said assembly further comprises ancillary electronic components mounted on said flexible printed circuit board and covered by said combined fibre alignment ferrule and lens cap component.

3. The assembly as claimed in claim 2, wherein an area of said first side of said flexible printed circuit board has a first region that substantially matches an outline of said contact region of a base of said combined fibre alignment ferrule and lens cap component and said first region of said flexible printed circuit board has applied thereto a layer of adhesive, wherein said adhesive permits adjustment of attached components until a curing process is performed.

4. The assembly as claimed in claim 3, wherein said region whereon there is applied said adhesive is arranged in a concentric manner around a location of said photodiode.

5. The assembly as claimed in claim 4, wherein said combined fibre alignment ferrule and lens cap component is attached to said first side of said first region of said flexible printed circuit board by said adhesive.

6. The assembly as claimed in claim 3 wherein holes are formed through said first region of said flexible printed circuit board of sufficient diameter to permit said adhesive to flow though said holes when said adhesive is applied to said first region.

7. The assembly as claimed in claim 6 wherein said first region of said flexible printed circuit board has applied thereto a layer of said adhesive, wherein said adhesive is sufficiently fluid to flow through said holes in said first region, and wherein said adhesive permits adjustment of attached components until a curing process is performed.

8. The assembly as claimed in claim 7 wherein said combined fibre alignment ferrule and lens cap component and said stiffener are attached to said flexible printed circuit board by said adhesive applied to said first region and wherein said adhesive has been made to flow through said holes in said first region.

9. The assembly in claim 5 wherein a final position of said combined fibre alignment ferrule and lens cap component is adjusted to provide satisfactory coupling of optical signals to said photodiode; and after said adjustment is completed said adhesive is subject to a curing process to fix said position of said combined fibre alignment ferrule and lens cap component.

10. The assembly as claimed in claim 1, wherein a vent hole is provided to allow gas pressure differences between an inside of said combined fibre alignment ferrule and lens cap component and an external atmosphere to be released.

11. A method of assembly of electronic components to provide means for reception of data using an optical fibre, said method comprising:
providing a flexible printed circuit board, wherein said flexible printed circuit board is configured to have conducting traces in defined regions;
physically mounting directly on a first side of said flexible printed circuit board a photodiode and an amplifier;
providing a stiffener attached to said flexible printed circuit board, wherein said stiffener is attached to a second side of said flexible printed circuit board opposite to said photodiode and said amplifier and wherein said stiffener is attached in a region approximately concentric with said region of said printed circuit board upon which said photodiode and said amplifier are mounted;
providing on said flexible printed circuit board holes through said board configured to provide means of electrical connection between opposite sides of said flexible printed circuit board;
providing a combined fibre alignment ferrule and lens cap component, wherein said combined fibre alignment ferrule and lens cap component comprises:
a combined fibre alignment ferrule and lens cap component, configured to provide a receptacle with defined physical alignment for an optical fibre, and to further configured to provide a cover region configured to provide an hermetic seal for said amplifier and said photodiode, and which is further configured to hold a lens in an opening between the end of said fibre and said photodiode a lens which is configured to focus light from said optical fibre on to said photodiode;
physically attaching said combined fibre alignment ferrule and lens cap component to said flexible printed circuit board so as to provide an hermetic seal for said photodiode and amplifier;
aligning a position of said combined fibre alignment ferrule and lens cap component such that said lens within said combined fibre alignment ferrule and lens cap component is able to focus light from said optical fibre onto said photodiode.

12. A method of assembly of electronic components as claimed in claim 11 wherein said combined fibre alignment ferrule and lens cap component is configured to cover said photodiode and said amplifier on said flexible printed circuit board.

13. A method of assembly of electronic components as claimed in claim 12, wherein said combined fibre alignment ferrule and lens cap component is attached to said flexible printed circuit board using an adhesive, wherein said adhesive is configured to permit adjustment of said position of said fibre alignment ferrule and lens cap assembly before curing of said adhesive.

14. A method of assembly of electronic components as claimed in claim 11, wherein at least one said hole is provided within a region of said flexible printed circuit board covered by said combined fibre alignment ferrule and lens cap component.

15. A method of assembly of electronic components as claimed in claim 14 wherein connections between said conductive traces on said flexible printed circuit board and said photodiode are made via said at least one hole provided within said region of said flexible printed circuit board.
